(19) United States
(12) Patent Application Publication
(10) Pub. No.: US 2017/0161557 A9
(43) Pub. Date: Jun. 8, 2017

(54) Biometric Imaging Devices and Associated Methods

(71) Applicant: SiOnyx, LLC, Beverly, MA (US)

(72) Inventors: Stephen D. Saylor, Annisquam, MA (US); Martin U. Pralle, Wayland, MA (US); James E. Carey, Waltham, MA (US); Homayoon Haddad, Beaverton, OR (US)

(73) Assignee: SIOnyx, Inc., Beverly, MA (US)

(21) Appl. No.: 14/761,854

(22) PCT Filed: Jan. 17, 2014
(86) PCT No.: PCT/US2014/012135

§ 371 Date: Jul. 17, 2015

Related U.S. Application Data
(63) Continuation of application No. 14/158,684, filed on Jan. 17, 2014, now abandoned.
Application No. PCT/US2014/012135 is a continuation of application No. 14/158,684, filed on Jan. 17, 2014, now abandoned.
Application No. 14/158,684 is a continuation-in-part of application No. 13/549,107, filed on Jul. 13, 2012, now abandoned.
(60) Provisional application No. 61/849,099, filed on Jan. 17, 2013.
(60) Provisional application No. 61/849,099, filed on Jan. 17, 2013.
(60) Provisional application No. 61/507,488, filed on Jul. 13, 2011.

(51) Int. Cl. G06K 9/00; H04N 5/33

(52) U.S. Cl. CPC G06K 9/00604; H04N 5/33

(57) ABSTRACT

Systems, devices, and methods for authenticating an individual or user using biometric features is provided. In one aspect, for example, a system for authenticating a user through identification of at least one biometric feature can include an active light source capable of emitting electromagnetic radiation having a peak emission wavelength at from about 700 nm to about 1200 nm, where the active light source is positioned to emit the electromagnetic radiation to impinge on at least one biometric feature of the user, and an image sensor having infrared light-trapping pixels positioned relative to the active light source to receive and detect the electromagnetic radiation upon reflection from the at least one biometric feature of the user. The system can further include a processing module functionally coupled to the image sensor and operable to generate an electronic representation of the at least one biometric feature of the user from detected electromagnetic radiation, and an authentication module functionally coupled to the processing module that is operable to receive and compare the electronic representation to an authenticated standard of the at least one biometric feature of the user to provide authentication of the user.

### PRIORITY DATA

This application claims the benefit of U.S. Provisional Patent Application Ser. No. 61/849,099, filed on Jan. 17, 2013, which is incorporated herein by reference in its entirety. This application is also a continuation-in-part of U.S. patent application Ser. No. 13/549,107, filed on Jul. 13, 2012, which claims the benefit of U.S. Provisional Patent Application Ser. No. 61/507,488, filed on Jul. 13, 2011, each of which is incorporated herein by reference in its entirety.

### BACKGROUND

Biometrics is the study of signatures of a biological origin that can uniquely identify individuals. The use of biometric technology has increased in recent years, and can be classified into two groups, cooperative identification and non-cooperative identification. Cooperative biometric identification methods obtain biometric readings with the individual's knowledge, and typical examples include identification of finger prints, palm prints, and iris scans. Non-cooperative biometric identification methods obtain biometric readings without the individual's knowledge, and typical examples include detection of facial, speech, and thermal signatures of an individual. This disclosure focuses on devices and methods that use an imaging device to detect various biometric signatures of both cooperative and non-cooperative individuals.

Facial and iris detection are two examples of biometric signatures used to identify individuals for security or authentication purposes. These methods of detection commonly involve two independent steps, an enrollment phase where biometric data is collected and stored in a database and a query step, where unknown biometric data is compared to the database to identify the individual. In both of these steps, a camera can be used to collect and capture the images of the individual's face or iris. The images are processed using algorithms that deconstruct the image into a collection of mathematical vectors which, in aggregate, constitute a unique signature of that individual.

Digital imaging devices are often utilized to collect such image data. For example, charge-coupled devices (CCDs) are widely used in digital imaging, and have been later improved upon by complementary metal-oxide-semiconductor (CMOS) imagers having improved performance. Many traditional CMOS imagers utilize so called front side illumination (FSI). In such cases, electromagnetic radiation is incident upon the semiconductor surface containing the CMOS transistors and circuits. Backside illumination (BSI) CMOS imagers have also been used and differ from FSI imagers in that the electromagnetic radiation is incident on the semiconductor surface opposite the CMOS transistors and circuits.

In biometric identification methodologies such as iris detection and, to a lesser degree, facial recognition, the pigmentation of the iris and/or skin can affect the ability to collect robust data, both in the enrollment phase as well as in the future query phase. Pigmentation can mask or hide the unique structural elements that define the values of the signature mathematical vectors. The ability to collect biometric data at many wavelengths, such as the visible and infrared, reduces the impact of pigmentation and improves the robustness of biometric identification methods.

### SUMMARY

The present disclosure provides systems, devices, and methods for authenticating an individual or user through the identification of biometric features, including iris features and facial features such as ocular spacing and the like. More specifically, the present disclosure describes a system having an active light source capable of emitting infrared (IR) electromagnetic radiation toward an individual, an IR sensitive image sensor arranged to detect the reflected IR radiation, and an indicator to provide notification that the user is operating in an authenticated or authorized mode. In some specific cases, 940 nm light can be emitted by the active light source for use in authenticating the individual.

In one aspect, for example, a system for authenticating a user through identification of at least one biometric feature can include an active light source capable of emitting electromagnetic radiation having a peak emission wavelength at from about 700 nm to about 1200 nm, where the active light source is positioned to emit the electromagnetic radiation to impinge on at least one biometric feature of the user, and an image sensor having infrared light-trapping pixels positioned relative to the active light source to receive and detect the electromagnetic radiation upon reflection from the at least one biometric feature of the user. The light trapping pixels have a structural configuration to facilitate multiple passes of infrared electromagnetic radiation therethrough. The system can further include a processing module functionally coupled to the image sensor and operable to generate an electronic representation of the at least one biometric feature of the user from detected electromagnetic radiation, an authentication module functionally coupled to the processing module that is operable to receive and compare the electronic representation to an authenticated standard of the at least one biometric feature of the user to provide authentication of the user, and an authentication indicator functionally coupled to the authentication module operable to provide notification that the user is indeed authenticated. The authentication indicator can provide notification to various entities, including, without limitation, the user, an operator of the system, an electronic system, an interested observer, or the like.

Various image sensor and image sensor configurations are contemplated, and any image sensor capable of detecting sufficient infrared electromagnetic radiation to function as described herein is considered to be within the present scope. In one aspect, for example, the image sensor can be a CMOS image sensor. In another aspect, the image sensor can be a front side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 20% for electromagnetic radiation having at least one wavelength of greater than 900 nm. In yet another aspect, the image sensor can be a front side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 30% for electromagnetic radiation having at least one wavelength of greater than 900 nm. In a further aspect, the image sensor can be a back side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 40% for electromagnetic radiation having at least one wavelength of greater than 900 nm. In a further aspect, the image sensor can be a back side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 50% for electromagnetic radiation having at least one wavelength of greater than 900 nm. Additionally, it is noted that in some aspects the image sensor can also be capable of detecting electromagnetic radiation having wavelengths of from about 400 nm to about 700 nm, wherein the image sensor has an external quantum efficiency of great than 40% at 550 nm.

In another aspect, the image sensor can be capable of capturing the reflected electromagnetic radiation with sufficient detail to facilitate the authentication of the user using electromagnetic radiation emitted from the active light source having at least one wavelength of from about 700 nm to about 1200 nm and having a scene irradiance impinging on the user at a distance that is in the range of up to about 24 inches and that is less than about 5 uW/cm2. In yet another aspect, the image sensor can be capable of capturing the reflected electromagnetic radiation with sufficient detail to facilitate the authentication of the user using the electromagnetic radiation emitted from the active light source having a peak emission wavelength of about 940 nm and having a scene irradiance impinging on the user at up to about 18 inches that is less than about 5 uW/cm2.

Furthermore, various active light sources are contemplated, and any active light source capable of emitting sufficient infrared electromagnetic radiation to function as described herein is considered to be within the present scope. In one aspect, for example, the active light source can have a peak emission wavelength at from about 850 nm to about 1100 nm. In another aspect, the active light source can have a peak emission wavelength at about 940 nm. In a further aspect, the active light source can generate electromagnetic radiation having an intensity of at least 0.1 mW/cm² at 940 nm. The active light source can be operated in a continuous manner, a strobed manner, a user activated manner, an authentication activated manner, a structured light manner, or a combination thereof. In some aspects, the active light source can include two or more active light sources each emitting electromagnetic radiation at distinct peak emission wavelengths. In one example, two or more active light sources can emit electromagnetic radiation at about 850 nm and about 940 nm. In another example, the system can determine if there is sufficient ambient light at 850 nm or 940 nm to not require the use of the active light source, and thus the active light source need not be activated if so desired.

In another aspect, the system can further include a synchronization component functionally coupled between the image sensor and the active light source, where the synchronization component can be capable of synchronizing the capture of reflected electromagnetic radiation by the image sensor with emission of electromagnetic radiation by the active light source. Non-limiting examples of synchronization components can include circuitry, software, or combinations thereof, configured to synchronize the image sensor and the active light source.

In another aspect, the system can include a processor element that allows for the subtraction background ambient illumination by comparing an image frame from a moment where the active light source is not active and an image from where the active light source is active.

A variety of physical configurations for systems according to aspects of the present disclosure are contemplated, and it should be understood that the present disclosure is not limited merely to those configurations disclosed herein. In one aspect, for example, at least the active light source, the image sensor, the processing module, and the authentication indicator can be integrated into an electronic device. Non-limiting examples of such electronic devices can include a hand held electronic device, a cellular phone, a smart phone, a tablet computer, a personal computer, an automated teller machine (ATM), a kiosk, a credit card terminal, a cash register, a television, a video game console, or an appropriate combination thereof. In one specific aspect, the image sensor can be incorporated into a cameo or front facing camera module of the electronic device.

The present disclosure additionally provides a method of authorizing a user with an electronic device for using a secure resource. Such a method can include delivering electromagnetic radiation from an active light source in the electronic device to impinge on the user such that the electromagnetic radiation reflects off of at least one biometric feature of the user, where the electromagnetic radiation has a peak emission wavelength of from about 700 nm to about 1200 nm, and detecting the reflected electromagnetic radiation at an image sensor positioned in the electronic device. The image sensor can include infrared light-trapping pixels positioned relative to the active light source to receive and detect the electromagnetic radiation upon reflection from the at least one biometric feature of the user, and the light trapping pixels can have a structural configuration to facilitate multiple passes of infrared electromagnetic radiation therethrough. The method can further include generating an electronic representation of the at least one biometric feature of the user from the reflected electromagnetic radiation, comparing the electronic representation to an authenticated standard of the at least one biometric feature of the user to authenticate the user as an authenticated user, and authorizing the authenticated user to use at least a portion of the secure resource. In some aspects, the method can also include providing notification to the user that authorization was successful and that an authorization state is active.

### BRIEF DESCRIPTION OF THE DRAWINGS

For a fuller understanding of the nature and advantage of the present invention, reference is being made to the following detailed description of preferred embodiments and in connection with the accompanying drawings, in which:

FIG. 1 is a representation of a system for authenticating a user in accordance with one aspect of the present disclosure.

FIG. 2 is a representation of a system for authenticating a user in accordance with one aspect of the present disclosure.

FIG. 3 is a representation of a system for authenticating a user in accordance with one aspect of the present disclosure.

FIG. 4 is a representation of a system for authenticating a user in accordance with one aspect of the present disclosure.

FIG. 5 is a representation of an electronic device for authenticating a user in accordance with one aspect of the present disclosure.

FIG. 6 is a flow diagram of a method in accordance with another aspect of the present disclosure.

FIG. 7 is a graphical representation of spectral irradiance vs wavelength for solar radiation.

FIG. 8 is a representation of a light trapping pixel in accordance with one aspect of the present disclosure.

FIG. 9 is a representation of an image sensor pixel in accordance with one aspect of the present disclosure.

FIG. 10 is a representation of an image sensor pixel in accordance with one aspect of the present disclosure.

FIG. 11 is a representation of an image sensor pixel in accordance with one aspect of the present disclosure.

FIG. 12 is a representation of an image sensor array in accordance with one aspect of the present disclosure.

FIG. 13 is a schematic diagram of a six transistor image sensor in accordance with another aspect of the present disclosure.

FIG. 14a is a photograph showing an iris captured with a photoimager having a rolling shutter in accordance with another aspect of the present disclosure.

FIG. 14b is a photograph showing an iris captured with a photoimager having a global shutter in accordance with another aspect of the present disclosure.

FIG. 15 is an illustration of a time of flight measurement in accordance with another aspect of the present disclosure.

FIG. 16a is a schematic view of a pixel configuration for a photoimager array in accordance with another aspect of the present disclosure.

FIG. 16b is a schematic view of a pixel configuration for a photoimager array in accordance with another aspect of the present disclosure.

FIG. 16c is a schematic view of a pixel configuration for a photoimager array in accordance with another aspect of the present disclosure.

FIG. 17 is a schematic diagram of an eleven transistor image sensor in accordance with another aspect of the present disclosure.

FIG. 18 is a schematic view of a pixel configuration for a photoimager array in accordance with another aspect of the present disclosure.

FIG. 19 is a representation of an integrated system for identifying an individual in accordance with one aspect of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

Definitions

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the terms “electromagnetic radiation” and “light” can be used interchangeably, and can represent wavelengths across a broad range, including visible wavelengths (approximately 350 nm to 800 nm) and non-visible wavelengths (longer than about 800 nm or shorter than 350 nm). The infrared spectrum is often described as including a near infrared portion of the spectrum including wavelengths of approximately 800 to 1300 nm, a short wave infrared portion of the spectrum including wavelengths of approximately 1300 nm to 3 micrometers, and a mid and long wave infrared (or thermal infrared) portion of the spectrum including wavelengths greater than about 3 micrometers up to about 30 micrometers. These are generally and collectively referred to herein as “infrared” portions of the electromagnetic spectrum unless otherwise noted.

As used herein, “shutter speed” refers to the time duration of a camera's shutter remain open while an image is captured. The shutter speed directly proportional to the exposure time, i.e. the duration of light reaching the image sensor. In other words, the shutter speed controls the amount of light that reaches the photosensitive image sensor. The slower the shutter speed, the longer the exposure time. Shutter speeds are commonly expressed in seconds and fractions of seconds. For example, 4, 2, 1, ½, ¼, ⅛, 1/15, 1/30, 1/60, 1/125, 1/250, 1/500, 1/1000, 1/2000, 1/4000, 1/8000. Notably, each speed increment halves the amount of light incident upon the image sensor.

As used herein, “active light source” refers to light that is generated by a device or system for the purpose of authenticating a user.

As used herein, the term “detection” refers to the sensing, absorption, and/or collection of electromagnetic radiation.

As used herein, the term “scene irradiance” refers to the areal density of light impinging on a known area or scene.

As used herein, “secure resource” can include any resource that requires authentication in order for a user to access. Non-limiting examples can include websites, remote servers, local data, local software access, financial data, high security data, databases, financial transactions, and the like.

As used herein, the term “textured region” refers to a surface having a topology with nano- to micron-sized surface variations. Such a surface topology can be formed by any appropriate technique, including, without limitation, irradiation with a laser pulse or laser pulses, chemical etching, lithographic patterning, interference of multiple simultaneous laser pulses, reactive ion etching, and the like. While the characteristics of such a surface can be variable depending on the materials and techniques employed, in one aspect such a surface can be several hundred nanometers thick and made up of nanocrystallites (e.g. from about 10 to about 50 nanometers) and nanopores. In another aspect, such a surface can include micron-sized structures (e.g. about 0.5 μm to about 10 μm). In yet another aspect, the surface can include nano-sized and/or micron-sized structures from about 5 nm and about 10 μm. In another aspect, such a surface is comprised of nano-sized and/or micron-sized structures from about 100 nm to 1 μm. In another aspect, the surface structures are nano-sized and/or micron-sized with heights from about 200 nm to 1 μm and spacing from peak to peak from about 200 nm to 2 μm. It should be mentioned that the textured region can be ordered or disordered or have local order but no long range order or have a repeated pattern of disordered structures.

As used herein, the terms “surface modifying” and “surface modification” refer to the altering of a surface of a semiconductor material using a variety of surface modification techniques. Non-limiting examples of such techniques include lithographically patterning, plasma etching, reactive ion etching, porous silicon etching, lasing, chemical etching (e.g. anisotropic etching, isotropic etching), nanoimprinting, material deposition, selective epitaxial growth, and the like, including combinations thereof. In one specific aspect, surface modification can include creating nano-sized and/or micron-sized features on the surface of a semiconductor material, such as silicon. In one specific aspect, surface modification can include processes primarily using laser radiation to create nano-sized and/or micron-sized features on the surface of a semiconductor material, such as silicon. In one specific aspect, surface modification can include processes using primarily laser radiation or laser radiation in combination with a dopant, whereby the laser radiation facilitates the incorporation of the dopant into a surface of the semiconductor material. Accordingly, in one aspect surface modification includes doping of a substrate such as a semiconductor material.

As used herein, the term “target region” refers to an area of a substrate that is intended to be doped, textured, or surface modified. The target region of the substrate can vary as the surface modifying process progresses. For example, after a first target region is doped or surface modified, a second target region may be selected on the same substrate.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

Secure and robust identification of individuals, particularly those individuals using or attempting to access some form of secure resource or perform a financial transaction, is a top priority for many businesses, communities, governments, financial institutions, e-commerce, and the like. For example, accurate authentication of an individual through imaging of a biometric feature can enable numerous activities such as financial transactions, computer and electronic device access, airline and other transportation, accessing a secure location, and the like.

As has been described, one problem inherent to biometric systems imaging iris features and other facial features is interference due to pigmentation. To reduce this potential interference, a biometric imaging device capturing light wavelengths in the range of 800 nm to 1300 nm (the near infrared) can be used. Iris pigmentation in this wavelength range is substantially transparent and therefore light photons are transmitted through the pigment and reflect off of structural elements of interest for the identification, such as, for example, ligament structures in the iris.

CCDs and CMOS image sensors are based on silicon as the photodetecting material and typically have low sensitivity to near infrared light in the wavelength range of interest. As such, these systems tend to perform poorly when attempting to capture an iris signature from a distance, such as, for example, greater than 18 inches, and/or with a short integration time. A biometric identification system using these types of image sensors requires an increased intensity of infrared light being emitted in order to compensate for the low near infrared sensitivity. In mobile electronic devices, emitting the increased near infrared intensity results in rapid power consumption and reduces battery life. Reducing the amount of emitted light in a mobile system is desirable to reduce power consumption. Higher intensity infrared light is also undesirable because it can become damaging to ocular tissue at close distances. In addition, depending on the wavelength, near infrared light emitting diodes can become visible to the human eye if the intensity is large enough, and this is undesirable for aesthetic reasons.

The present disclosure describes a system having an active light source capable of emitting infrared (IR) electromagnetic radiation toward an individual, an IR sensitive image sensor arranged to detect the reflected IR radiation, and an indicator, such as for example, an authentication indicator, to provide notification that the user is operating in an authenticated or authorized mode. The present disclosure also provides an efficient biometric device that can operate in low light conditions with good signal to noise ratio and high quantum efficiencies in the visible and infrared (IR) spectrum, and requires a miminum amount of emitted infrared light to function. Using an IR light source, as opposed to purely visible light, the present system can image and facilitate the identification of unique biometric features, including in some aspects the textured patterns of the iris, remove existing light variations, and reduce pattern interference from facial and corneal reflections, thereby capturing more precise facial feature information.

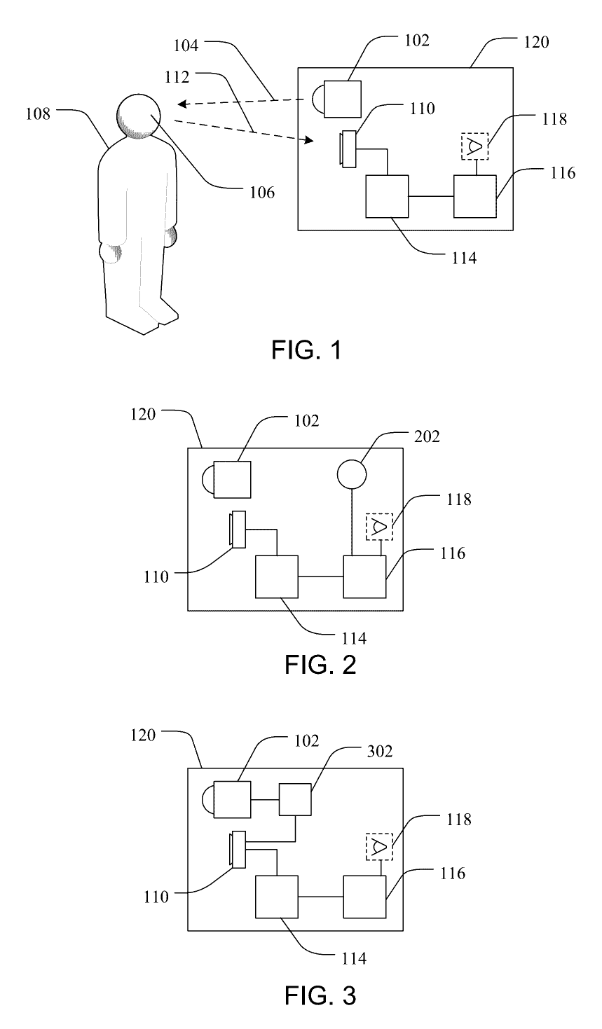

In one aspect, as is shown in FIG. 1 for example, a system for authenticating a user through identification of at least one biometric feature can include an active light source 102 capable of emitting electromagnetic radiation 104 having a peak emission wavelength in the infrared (including the near infrared). The active light source 102 is positioned to emit the electromagnetic radiation 104 to impinge on at least one biometric feature 106 of a user 108. The system can further include an image sensor 110 having infrared light-trapping pixels positioned relative to the active light source to receive and detect the electromagnetic radiation upon reflection 112 from the at least one facial feature 106 of the user 108. In some aspects, the image sensor can be an IR enhanced detecting sensor. A processing module 114 can be functionally coupled to the image sensor 110 and can be operable to generate an electronic representation of the at least one biometric feature 106 of the user 108 from detected electromagnetic radiation. Additionally, an authentication module 116 can be functionally coupled to the processing module 114 and can be operable to receive and compare the electronic representation to an authenticated standard 118 of the at least one biometric feature 106 of the user 108 to provide authentication of the user 108. A housing 120 is contemplated in some aspects to support various components of the system. It is noted however, that the physical configurations of such housings, as well as whether or not a particular component is physically located within a housing, is not to be considered limiting.

In some aspects, as is shown in FIG. 2, the system can include an authentication indicator 202 functionally coupled to the authentication module 116. The authentication indicator 202 can thus provide notification that the user 108 has been authenticated by the system. In some aspects, the indicator can notify a user when the device is operating in a secure mode or in a non-secure mode. A wide variety of authentication indicators and indicator functionality are contemplated, and any indicator providing such a notification is considered to be within the present scope. The nature of the indicator may also vary depending on the physical nature of the system or electronic device in which it is utilized. For example, in some aspects the indicator can be a dedicated indicator such as an LED, an audible signal, or the like. In other aspects, the indicator can be a change or variation in an electronic screen, such an alternate set of menus for authenticated users in some aspects or the appearance of a symbol or icon, such as a lock or dollar sign icon, that indicates a secure mode in other aspects. The indicator can also include a change in the physical state of an object, such as the opening of a door, gate, or other barrier. Thus the authentication indicator 202 can be located within a housing 120 or physically linked to the major components of the system as shown in FIG. 2, or the indicator can be located apart from the system/housing and activated remotely. It is noted for FIG. 2 and subsequent figures, callout item numbers from previous figures (e.g. FIG. 1) are intended to incorporate the descriptions from the description of those figures. In these cases, the item may or may not be redescribed or discussed, and the previous description will apply to an appropriate extent.

In another aspect, as is shown in FIG. 3, the system can further include a synchronization component 302 functionally coupled between the image sensor 110 and the active light source 102 for synchronizing the capture of reflected electromagnetic radiation by the image sensor 110 with emission of electromagnetic radiation by the active light source 102. Additionally, in some aspects the synchronization can be processed by other components in the system such as, for example, the image sensor processor. The signal-to-noise ratio of the system can thus be improved by aligning the capture of reflected electromagnetic radiation with the emission of electromagnetic radiation. In some aspects, the synchronization component 302 can independently control the emission duty cycle of the active light source 102 and the capture duty cycle of the image sensor 110, thus allowing tuning of capture relative to emission. For example, variable delay in the reflected electromagnetic radiation due to a variation in the distance from the active light source to the user can be compensated for via adjustment to the timing and/or width of the capture window of the image sensor. It is contemplated that the synchronization component can include physical electronics and circuitry, software, or a combination thereof to facilitate the synchronization.

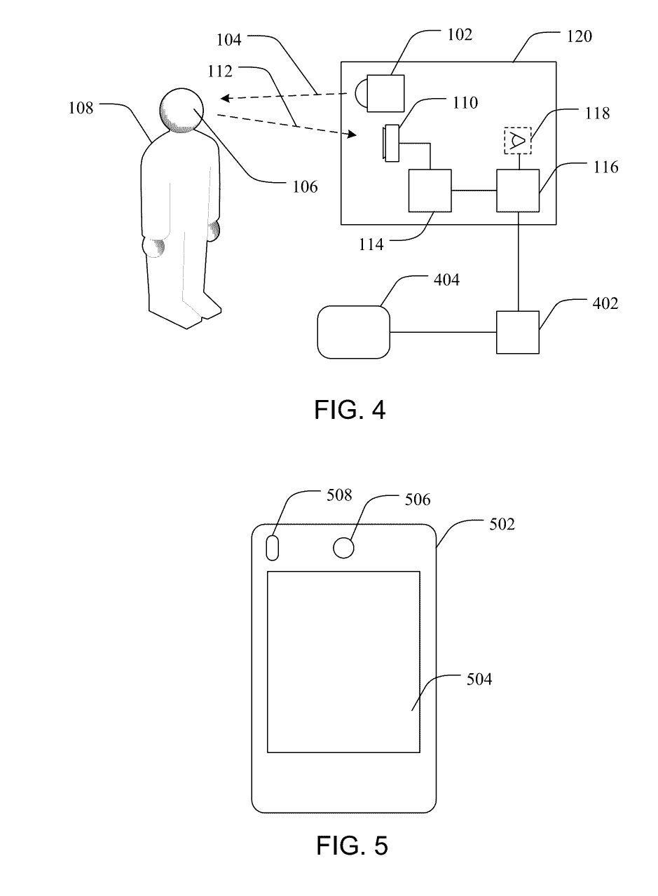

In another aspect, a system for authorizing a user on a secure resource is provided. The secure resource can be the device itself, access to a particular portion of the device, a collection of data, a website, remote server, etc. Such a system can include components as previously described, including equivalents, to authenticate a user. As is shown in FIG. 4, such a system can further include an authorization module 402 functionally coupled to the authentication module 116. The authorization module 402 can be operable to verify that the authentication of the user 108 has occurred and to allow access to at least a portion of a secure resource 404 based on the authentication. The authorization of an authenticated user can allow different levels of access to the secure resource depending on the authenticated individual. In other words, different types of users can have different authorization levels following authentication. For example, users of a secure resource will likely have lower access to the secure resource as compared to administrators.

The interactions and physical relation of the secure resource, the authorization module, and the authentication system can vary depending on the design of the system and the secure resource, and such variations are considered to be within the present scope. Returning to FIG. 4, for example, the authorization module 402 is shown at a distinct location from the authentication module 116. While this may be the case in some aspects, it is also contemplated that the modules be located proximal to one another or even integrated together, such as, for example, on-chip integration. In the case where the system is located within an electronic device, for example, at least one of the authentication module or the authorization module can be located therewithin. In another aspect, at least one of the authentication module or the authorization module can be located with the secure resource. In some aspects, the secure resource can be physically separate and distinct from the electronic device, while in other aspects the secure resource can be located within the electronic device. This later may be the case for a secured data base or other secured information stored locally on a device. Thus the present disclosure contemplates that the component parts of the system can be physically incorporated together or they can be separated where desired. In other aspects, the secure resource can be a gateway to a remote secure resource. One example of a remote secure resource would include a financial system. In such cases, the authorization of the user can allow the user to be verified in a financial transaction. Another example of a remote secure resource would include a database of unique individuals' biometric signatures. In such cases, the user can be identified from a large database of individuals and then given or denied access to a resource, such as an airplane, a building, or a travel destination.

The degree of integration can also be reflected in the physical design of the system and/or the components of the system. Various functional modules can be integrated to varying degrees with one another and/or with other components associated with the system. In one aspect, for example, at least one of the authentication module or the authorization module can be integrated monolithically together with the image sensor. In some cases, such integration can be separate from a CPU of the electronic device. In one aspect, the system can be integrated into a mobile electronic device.

As has been described, the present systems can be incorporated into physical structures in a variety of ways. In one aspect, for example, at least the active light source, the image sensor, the processing module, and the authentication indicator are integrated into an electronic device. In another aspect, at least the active light source, the image sensor, and the processing module are integrated into an electronic device. It is contemplated that the system can be integrated into a wide variety of electronic devices, which would vary depending on the nature of the secure resource and/or the electronic device providing the authentication/authorization. Non-limiting examples of such devices can include hand held electronic devices, mobile electronic devices, cellular phones, smart phones, tablet computers, personal computers, automated teller machines (ATM), kiosks, credit card terminals, television, video game consoles, and the like, including combinations thereof where appropriate. FIG. 5 shows one non-limiting example of a smart phone 502. In this case, the smartphone 502 includes the authorization system incorporated therein, the majority of which is not shown. The smartphone includes a visual display 504 and, in this case, a cameo camera 506 having an incorporated image sensor as has been described. In this case, a user can activate the authentication system, align the image of the user's face that is captured by the cameo camera 506 in the visual display 504, and proceed with authentication by the system. In some aspects, an authentication indicator 508 can be incorporated into the device to provide notification to the user that the device is in a secure mode or a non-secure mode. In some aspects, such a notification can also be provided by the screen 504. It is noted that, while the cameo camera of the smartphone is used in this example, non-cameo cameras/imaging devices associated with a smartphone or any other electronic device can be similarly utilized. In one aspect, a cameo camera and an additional camera module dedicated to biometric identification or gesture identification can be included onto the smart phone. Additionally, in some aspects a stand-alone camera can be integrated into a device or system as shown in FIG. 5, as well as into internet or local network systems. In some aspects, the additional biometric camera module can include a filter or filters to reject any light except for a small range on near infrared wavelengths.

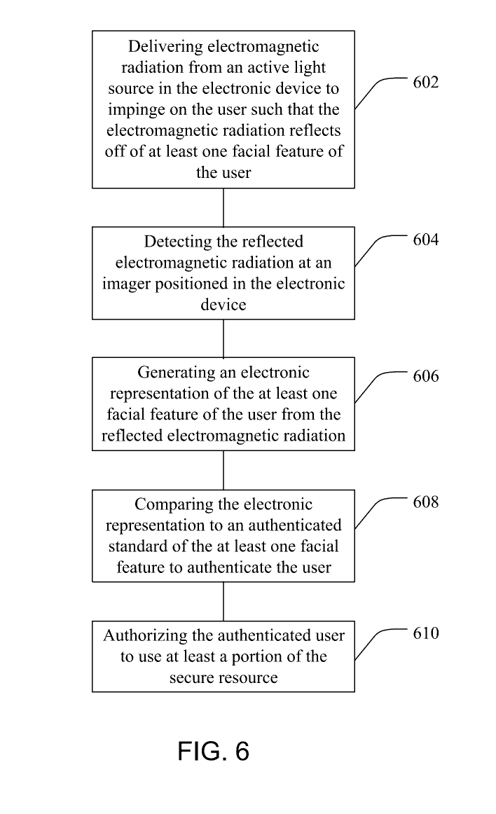

The present disclosure additionally provides methods for authorizing a user with an electronic device for using a secure resource. In one aspect, as is shown in FIG. 6, for example, such a method can include 602 delivering electromagnetic radiation from an active light source in the electronic device to impinge on the user such that the electromagnetic radiation reflects off of at least one biometric feature of the user, where the electromagnetic radiation can have a peak emission wavelength of from about 700 nm to about 1200 nm, and 604 detecting the reflected electromagnetic radiation at an image sensor positioned in the electronic device, wherein the image sensor includes infrared light-trapping pixels positioned relative to the active light source to receive and detect the electromagnetic radiation upon reflection from the at least one biometric feature of the user, the light trapping pixels having a structural configuration to facilitate multiple passes of infrared electromagnetic radiation therethrough. The method can also include 606 generating an electronic representation of the at least one biometric feature of the user from the reflected electromagnetic radiation, 608 comparing the electronic representation to an authenticated standard of the at least one biometric feature of the user to authenticate the user as an authenticated user, and 610 authorizing the authenticated user to use at least a portion of the secure resource. In another aspect, the method can include providing notification to the user that authorization was successful and that an authorization state is active. Additionally, it is contemplated that in some aspects the method can include periodically authenticating the user while the secure resource is in use, or in other aspects, continuously authenticating the user while the secure resource is in use.

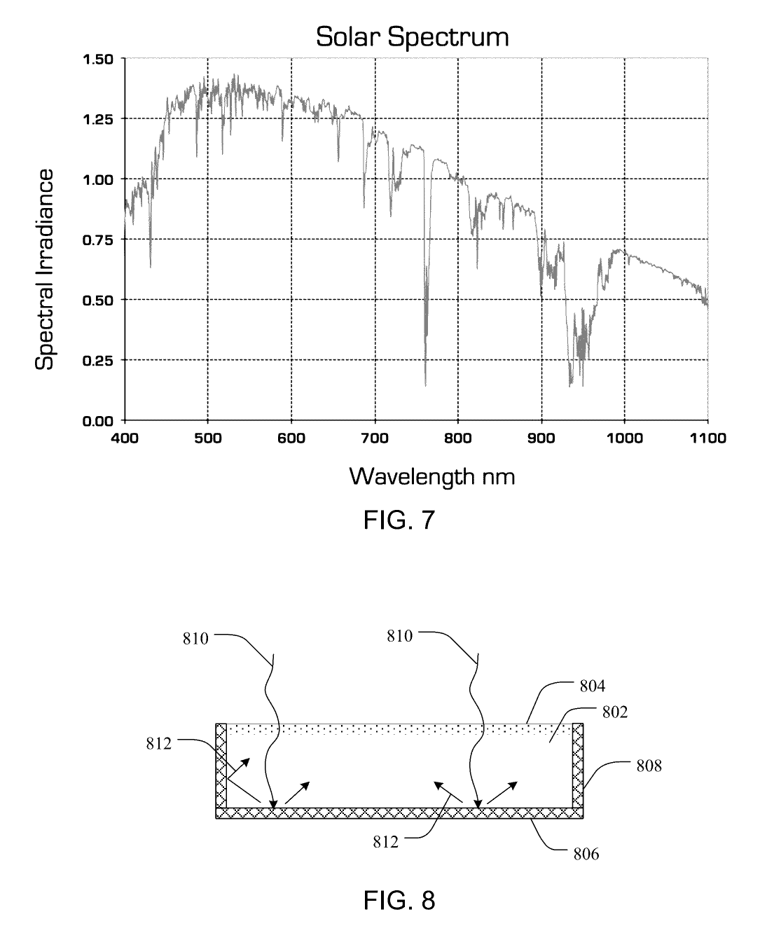

Various active light sources are contemplated, and any such source capable of emitting IR light is considered to be within the present scope. In one aspect, for example, the active light source can emit electromagnetic radiation having a peak emission wavelength of from about 700 nm to about 1200 nm. In another aspect, the active light source can emit electromagnetic radiation having a peak emission wavelength of greater than about 900 nm. In yet another aspect, the active light source can emit electromagnetic radiation having a peak emission wavelength of from about 850 nm to about 1100 nm. In a further aspect, the active light source can emit electromagnetic radiation having a peak emission of about 940 nm. It can be particularly beneficial to utilize light having wavelengths around 940 nm light due to a reduction in the amount of background light coming from the sun's spectrum. Wavelengths of light around 940 nm are filtered to some degree from the solar spectrum by water in the atmosphere. As such background noise in this wavelength region is reduced when ambient light includes sunlight. As is shown in FIG. 7, there is a filtered region of the sun's spectrum where the background spectral irradiance is lower at 940 nm. By utilizing an active light source emitting at about 940 nm, the signal to noise ratio of the system can be increased, the efficiency of the authentication can be increased, the intensity of the active light source can be decreased to conserve power, and the functionality in outdoor situations is improved. In one specific aspect, the active light source can generate electromagnetic radiation having an intensity of at least about 0.1 mW/cm² at 940 nm for effective authentication.

The active light source can be operated in a variety of modes, depending on the image capture and/or authentication methodology employed. For example, the active light source can be operated a continuous manner, a strobed manner, a user activated manner, an authentication activated manner, in a specific patterned manner, or the like, including combinations thereof. As has been described, the active light source can be intermittently activated to correspond with the imaging duty cycle. In those aspects where continuous authentication is desired during access to a secure resource, the active light source can continuously emit light, intermittently emit light, and the like throughout the access of the secure resource.

Turning to image sensors, structure and design can vary depending on the nature of the device into which the image sensor is incorporated, and depending on various system design parameters. As has been described, the image sensors can include light trapping pixels having a structural configuration to facilitate multiple passes of infrared electromagnetic radiation therethrough. As one example, FIG. 8 shows a pixel having a device layer 802 and a doped or junction region 804. The pixel is further shown having a textured region 806 coupled to a side of the device layer 802 that is opposite the doped region 804. Any portion of the pixel can be textured, depending on the image sensor design. FIG. 8 also shows side light reflecting regions 808 to demonstrate further light trapping functionality. The light reflecting regions (808) can be textured regions, mirrors, bragg reflectors, filled trench structures, and the like. Light 810 is also shown interacting with the device layer 802 of the pixel. The textured and reflective regions (either 806 or 808) reflect light back into the device layer 802 when contacted, as is shown at 812. In some aspects, 806 and/or 808 can be trench isolation elements for isolating pixels in an image sensor device. Thus the light has been trapped by the pixel, facilitating further detection as the reflected light 812 passed back through the pixel. In addition, trench isolation elements can trap photoelectrons within a pixel, facilitating reduced cross-talk and higher modulation transfer function (MTF) in an image sensor. It is noted that interaction with a textured region can cause light to reflect, scatter, diffuse, etc., to increase the optical path of the light. This can be accomplished by any element capable of scattering light. In other aspects, mirrors, Bragg reflectors, and the like may be utilized in addition to or instead of a textured region.

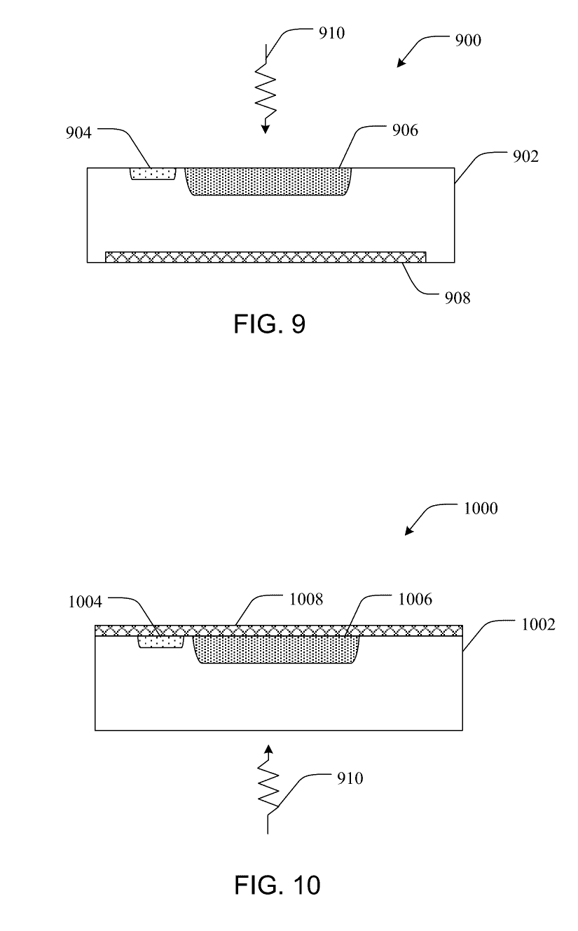

FIG. 9 shows one exemplary embodiment of a front side illuminated image sensor device that is capable of operation in low light conditions with good signal to noise ratio and high quantum efficiencies in the visible and IR light spectrum. The image sensor device 900 can include a semiconductor device layer 902 with a thickness of less than about 10 microns, at least two doped regions 904, 906 forming a junction, and a textured region 908 positioned to interact with incoming electromagnetic radiation 910. In other aspects, the thickness of the semiconductor device layer 902 can be less than 5 microns. In another aspect, the device layer thickness can be less than 7 microns. In yet another aspect, the device layer thickness can be less than 2 microns. A lower limit for thickness of the device layer can be any thickness that allows functionality of the device. In one aspect, however, the device layer can be at least 10 nm thick. In another aspect, the device layer can be at least 100 nm thick. In yet another aspect, the device layer can be at least 500 nm thick.

In one aspect, such a front side illuminated image sensor can have an external quantum efficiency of at least about 20% for electromagnetic radiation having at least one wavelength of greater than 900 nm. In another aspect, the image sensor can have an external quantum efficiency of at least about 25% for electromagnetic radiation having at least one wavelength of greater than 900 nm. In other aspects, the external quantum efficiency for such a device can be at least 30%, at least 35%, or at least 40% for one wavelength greater than 900 nm. It is noted that the quantum efficiencies described can also be achieved at wavelengths of about 940 nm in some aspects. In other aspects, wavelengths of 850 nm can be utilized for these quantum efficiencies.

Devices according to aspects of the present disclosure can include a semiconductor device layer that is optically active, a circuitry layer, a support substrate, and the like. In some aspects, the semiconductor device layer can be a silicon device layer. FIG. 10 shows a similar image sensor that is back side illuminated. The image sensor device 1000 can include a semiconductor device layer 1002 with a thickness of less than about 10 microns, at least two doped regions 1004, 1006 forming a junction, and a textured region 1008 positioned to interact with incoming electromagnetic radiation 1010. In other aspects, the thickness of the semiconductor device layer 1002 can be less than 7 microns. In another aspect, the device layer thickness can be less than 5 microns. In yet another aspect, the device layer thickness can be less than 2 microns. A lower limit for thickness of the device layer can be any thickness that allows functionality of the device. In one aspect, however, the device layer can be at least 10 nm thick. In another aspect, the device layer can be at least 100 nm thick. In yet another aspect, the device layer can be at least 500 nm thick.

In one aspect, such a back side illuminated image sensor can have an external quantum efficiency of at least about 40% for electromagnetic radiation having at least one wavelength of greater than 900 nm. In another aspect, the image sensor can have an external quantum efficiency of at least about 50% for electromagnetic radiation having at least one wavelength of greater than 900 nm. In other aspects, the external quantum efficiency for such a device can be at least 55% or at least 60% or at least 65% for one wavelength greater than 900 nm. It is noted that the quantum efficiencies described can also be achieved at wavelengths of about 940 nm in some aspects.

Numerous configurations are contemplated, and any type of junction configuration is considered to be within the present scope. For example, the first and second doped regions can be distinct from one another, contacting one another, overlapping one another, etc. In some cases, an intrinsic region can be located at least partially between the first and second doped regions. Additionally, in some aspects the semiconductor device layer can be disposed on a bulk semiconductor layer, a semiconductor support layer, or on a semiconductor on insulator layer.

It is generally noted that, the textured region can be associated with an entire surface of the semiconductor (e.g. silicon) material or only a portion thereof. Additionally, in some aspects the textured region can be specifically positioned to maximize the absorption path length of the semiconductor material. In other aspects, a third doping can be included near the textured region to improve the collection of carriers generated near the textured region.

Further details regarding such photosensitive devices have been described in U.S. application Ser. No. 13/164,630, filed on Jun. 20, 2011, which is incorporated herein by reference in its entirety.

Additionally, whether frontside illuminated or backside illuminated, the textured region can be positioned on a side of the semiconductor device layer opposite the incoming electromagnetic radiation. The textured region can also be positioned on a side of the semiconductor device layer adjacent the incoming electromagnetic radiation. In other words, in this case the electromagnetic radiation would contact the textured region prior to passing into the semiconductor device layer. Additionally, it is contemplated that the textured region can be positioned on both an opposite side and an adjacent side of the semiconductor device layer.

The semiconductor utilized to construct the image sensor can be any useful semiconductor material from which such an image sensor can be made having the properties described herein. In one aspect, however, the semiconductor device layer is silicon. It is noted, however, that silicon photodetectors have limited detectability of IR wavelengths of light, particularly for thin film silicon devices. Traditional silicon devices require substantial absorption depths in order to detect photons having wavelengths longer than about 700 nm. While visible light can be readily absorbed in the first few microns of a silicon layer, absorption of longer wavelengths (e.g. >900 nm) in silicon at a thin wafer depth (e.g. approximately 20 μm) is poor. The present image sensor devices can increase the electromagnetic radiation absorption in a thin layer of silicon.

The textured region can increase the absorption, increase the external quantum efficiency, and decrease response times and lag in an image sensor, particularly in the near infrared wavelengths. Such unique and novel devices can allow for fast shutter speeds thereby capturing images of moving objects in low light scenarios. Increased near infrared sensitivity in a silicon-based device can reduce the power needed in an active light source and increase the distance at which a device can capture an accurate biometric measurements of an individual.

While it is contemplated that the present system can include optics for increasing the capture distance between the device and the individual, the image sensor device having the textured region allows the system to function at low IR light intensity levels even at relatively long distances. This reduces energy expenditure and thermal management issues, increases battery life in a mobile device, as well as potentially decreasing side effects that can result from high intensity IR light. In one aspect, for example, the image sensor device can capture the electronic representation of an individual with sufficient detail to identify a substantially unique facial feature using electromagnetic radiation emitted from the active light source having at least one wavelength of from about 700 nm to about 1200 nm and having a scene irradiance impinging on the individual at from about 12 inches to about 24 inches that is less than about 5 uW/cm². In another aspect, the image sensor device can capture the electronic representation of an individual with sufficient detail to identify a substantially unique facial feature using electromagnetic radiation emitted from the active light source having at least one wavelength of from about 700 nm to about 1200 nm and having a scene irradiance impinging on the individual at from about 18 inches that is less than about 5 uW/cm². In yet another aspect, the image sensor device can capture the electronic representation of an individual with sufficient detail to identify a substantially unique facial feature using electromagnetic radiation emitted from the active light source having at least one wavelength of from about 800 nm to about 1000 nm and having a scene irradiance impinging on the individual at 18 inches that is from about 1 uW/cm² to about 100 uW/cm². In yet another aspect, the image sensor device can capture the electronic representation of an individual with sufficient detail to identify a substantially unique facial feature using electromagnetic radiation emitted from the active light source having at least one wavelength of from about 800 nm to about 1000 nm and having a scene irradiance impinging on the individual at 18 inches that is from about 1 uW/cm² to about 10 uW/cm².

As has been described, in some aspects the thickness of the silicon material in the device can dictate the responsivity and response time. Standard silicon devices need to be thick, i.e. greater than 50 μm in order to detect wavelengths deep into the near infrared spectrum, and such detection with thick devices results in a slow response and high dark current. The textured region is positioned to interact with electromagnetic radiation to increase the absorption of infrared light in a device, thereby improving the infrared responsivity while allowing for fast operation. Diffuse scattering and reflection can result in increased path lengths for absorption, particularly if combined with total internal reflection, resulting in large improvements of responsivity in the infrared for silicon pixels, photodetectors, pixel arrays, image sensors, and the like. Because of the increased path lengths for absorption, thinner silicon materials can be used to absorb electromagnetic radiation into the infrared regions. One advantage of thinner silicon material devices is that charge carriers are more quickly swept from the device, thus decreasing the response time. Conversely, thick silicon material devices sweep charge carriers therefrom more slowly, at least in part due to diffusion.

It is noted, however, that the semiconductor device layer can be of any thickness that allows electromagnetic radiation detection and conversion functionality, and thus any such thickness of semiconductor device layer is considered to be within the present scope. With that being said, thin silicon layer materials can be particularly beneficial in decreasing the response time and bulk dark current generation. As has been described, charge carriers can be more quickly swept from thinner silicon material layers as compared to thicker silicon material layers. The thinner the silicon, the less material the electron/holes have to traverse in order to be collected, and the lower the probability of a generated charge carrier encountering a defect that could trap or slow the collection of the carrier. Thus one objective to implementing a fast photo response is to utilize a thin silicon material for the semiconductor device layer of the image sensor. Such a device can be nearly depleted of charge carriers by the built in potential of the pixel and any applied bias to provide for a fast collection of the photo generated carriers by drift in an electric field. Charge carriers remaining in any undepleted region of the pixel are collected by diffusion transport, which is slower than drift transport. For this reason, it can be desirable to have the thickness of any region where diffusion may dominate to be much thinner than the depleted drift regions. In another aspect, the silicon material can have a thickness and substrate doping concentration such that an internal bias generates an electrical field sufficient for saturation velocity of the charge carriers.

Accordingly, image sensor devices according to aspects of the present disclosure provide, among other things, enhanced quantum efficiency in the infrared light portion of the optical spectrum for a given thickness of silicon. As such, high quantum efficiencies, low bulk generated dark current, and decreased response times or lag can be obtained for wavelengths in the near infrared. In other words, the sensitivity is higher and response time is faster than that found in thicker devices that achieve similar quantum efficiencies in the near infrared.

In addition to silicon, other semiconductor materials are contemplated for use in the image sensor devices of the present disclosure. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). Exemplary silicon materials, for example, can include amorphous silicon (a-Si), microcrystalline silicon, multicrystalline silicon, and monocrystalline silicon, as well as other crystal types. In another aspect, the semiconductor material can include at least one of silicon, carbon, germanium, aluminum nitride, gallium nitride, indium gallium arsenide, aluminum gallium arsenide, and combinations thereof.

Exemplary combinations of group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary combinations of group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlₓGa₁₋ₓAs), indium gallium arsenide (InGaAs, InₓGa₁₋ₓAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

Additionally, various types of semiconductor materials are contemplated, and any such material that can be incorporated into an electromagnetic radiation detection device is considered to be within the present scope. In one aspect, for example, the semiconductor material is monocrystalline. In another aspect, the semiconductor material is multicrystalline. In yet another aspect, the semiconductor material is microcrystalline. It is also contemplated that the semiconductor material can be amorphous. Specific nonlimiting examples include amorphous silicon or amorphous selenium.

The semiconductor materials of the present disclosure can also be made using a variety of manufacturing processes. In some cases the manufacturing procedures can affect the efficiency of the device, and may be taken into account in achieving a desired result. Exemplary manufacturing processes can include Czochralski (Cz) processes, magnetic Czochralski (mCz) processes, Float Zone (FZ) processes, epitaxial growth or deposition processes, and the like. It is contemplated that the semiconductor materials used in the present invention can be a combination of monocrystalline material with epitaxially grown layers formed thereon.

A variety of dopant materials are contemplated for the formation of the multiple doped regions, the textured region, or any other doped portion of the image sensor device, and any such dopant that can be used in such processes is considered to be within the present scope. It should be noted that the particular dopant utilized can vary depending on the material being doped, as well as the intended use of the resulting material. It is noted that any dopant known in the art can be utilized for doping the structures of the present disclosure.

Accordingly, the first doped region and the second doped region can be doped with an electron donating or hole donating species to cause the regions to become more positive or negative in polarity as compared to each other and/or the semiconductor device layer. In one aspect, for example, either doped region can be p-doped. In another aspect, either doped region can be n-doped. In one aspect, for example, the first doped region can be negative in polarity and the second doped region can be positive in polarity by doping with p+ and n− dopants. In some aspects, variations of n(−−), n(−), n(+), n(++), p(−−), p(−), p(+), or p(++) type doping of the regions can be used. Additionally, in some aspects the semiconductor material can be doped in addition to the first and second doped regions. The semiconductor material can be doped to have a doping polarity that is different from one or more of the first and second doped regions, or the semiconductor material can be doped to have a doping polarity that is the same as one or more of the first and second doped regions. In one specific aspect, the semiconductor material can be doped to be p-type and one or more of the first and second doped regions can be n-type. In another specific aspect, the semiconductor material can be doped to be n-type and one or more of the first and second doped regions can be p-type. In one aspect, at least one of the first or second doped regions has a surface area of from about 0.1 μm² to about 32 μm².

As has been described, the textured region can function to diffuse electromagnetic radiation, to redirect electromagnetic radiation, and to absorb electromagnetic radiation, thus increasing the QE of the device. The textured region can include surface features to increase the effective optical path length of the silicon material. The surface features can be cones, pyramids, pillars, protrusions, microlenses, quantum dots, inverted features and the like. Factors such as manipulating the feature sizes, dimensions, material type, dopant profiles, texture location, etc. can allow the diffusing region to be tunable for a specific wavelength. In one aspect, tuning the device can allow specific wavelengths or ranges of wavelengths to be absorbed. In another aspect, tuning the device can allow specific wavelengths or ranges of wavelengths to be reduced or eliminated via filtering.

As has been described, a textured region according to aspects of the present disclosure can allow a silicon material to experience multiple passes of incident electromagnetic radiation within the device, particularly at longer wavelengths (i.e. infrared). Such internal reflection increases the effective optical path length to be greater than the thickness of the semiconductor device layer. This increase in optical path length increases the quantum efficiency of the device without increasing the thickness of the substrate, leading to an improved signal to noise ratio. The textured region can be associated with the surface nearest the impinging electromagnetic radiation, or the textured region can be associated with a surface opposite in relation to impinging electromagnetic radiation, thereby allowing the radiation to pass through the silicon material before it hits the textured region. Additionally, the textured region can be doped. In one aspect, the textured region can be doped to the same or similar doping polarity as the semiconductor device layer so as to provide a doped contact region on the backside of the device. In another aspect, the textured region can be doped in same polarity as the semiconductor substrate but at higher concentration so as to passivate the surface with a surface field. In another aspect, the textured region can be doped in the opposite polarity as the semiconductor substrate to form a diode junction (or depletion region) at the interface of the textured layer and the adjacent substrate.

The textured region can be formed by various techniques, including lasing, chemical etching (e.g. anisotropic etching, isotropic etching), nanoimprinting, lithographically texturing, additional material deposition, reactive ion etching, and the like. One effective method of producing a textured region is through laser processing. Such laser processing allows discrete locations of the semiconductor device layer to be textured to a desired depth with a minimal amount of material removal. A variety of techniques of laser processing to form a textured region are contemplated, and any technique capable of forming such a region should be considered to be within the present scope. Laser treatment or processing can allow, among other things, enhanced absorption properties and increased detection of electromagnetic radiation.

In one aspect, for example, a target region of the silicon material can be irradiated with laser radiation to form a textured region. Examples of such processing have been described in further detail in U.S. Pat. Nos. 7,057,256, 7,354,792 and 7,442,629, which are incorporated herein by reference in their entireties. Briefly, a surface of a semiconductor material such as silicon is irradiated with laser radiation to form a textured or surface modified region. Such laser processing can occur with or without a dopant material. In those aspects whereby a dopant is used, the laser can be directed through a dopant carrier and onto the silicon surface. In this way, dopant from the dopant carrier is introduced into a target region of the silicon material. Such a region incorporated into a silicon material can have various benefits in accordance with aspects of the present disclosure. For example, the target region typically has a textured surface that increases the surface area of the laser treated region and increases the probability of radiation absorption via the mechanisms described herein. In one aspect, such a target region is a substantially textured surface including micron-sized and/or nano-sized surface features that have been generated by the laser texturing. In another aspect, irradiating the surface of the silicon material includes exposing the laser radiation to a dopant such that irradiation incorporates the dopant into the semiconductor. Various dopant materials are known in the art, and are discussed in more detail herein. It is also understood that in some aspects such laser processing can occur in an environment that does not substantially dope the silicon material (e.g. an argon atmosphere).

Thus the surface of the silicon material that forms the textured region is chemically and/or structurally altered by the laser treatment, which may, in some aspects, result in the formation of surface features appearing as nanostructures, microstructures, and/or patterned areas on the surface and, if a dopant is used, the incorporation of such dopants into the semiconductor material. In some aspects, such features can be on the order of 50 nm to 20 μm in size and can assist in the absorption of electromagnetic radiation. In other aspects, such features can be on the order of 200 nm to 2 μm in size. In other words, the textured surface can increase the probability of incident radiation being absorbed by the silicon material.

In another aspect, at least a portion of the textured region and/or the semiconductor material can be doped with a dopant to generate a passivating surface field; in aspects where the textured region is positioned on a side of the semiconductor device layer opposite the incoming electromagnetic radiation the passivating surface field is a so-called back surface field. A back surface field can function to repel generated charge carriers from the backside of the device and toward the junction to improve collection efficiency and speed. The presence of a back surface field also acts to suppress dark current contribution from the textured surface layer of a device. It is noted that in some aspects, surfaces of trenches, such as deep trench isolation, can be passivated to repel carriers. Furthermore, a back surface field can be created in such a trench in some aspects.

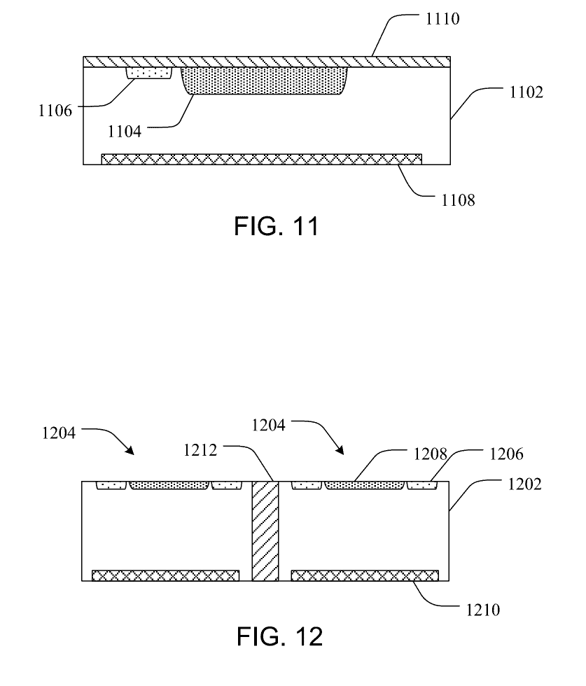

In another aspect, as is shown in FIG. 11, a semiconductor device layer 1102 can have a first doped region 1104, a second doped region 1106, and a textured region 1108 on an opposing surface to the doped regions. An antireflective layer 1110 can be coupled to the semiconductor device layer 1102 on the opposite surface as the textured layer 1108. In some aspects, the antireflective layer 1110 can be on the same side of the semiconductor device layer 1102 as the textured region (not shown). Furthermore, in some aspects a lens can be optically coupled to the semiconductor device layer and positioned to focus incident electromagnetic radiation into the semiconductor device layer.

In another aspect of the present disclosure, a pixel array is provided as the image sensor device. Such an array can include a semiconductor device layer having an incident light surface, at least two pixels in the semiconductor device layer, where each pixel includes a first doped region and a second doped region forming a junction, and a textured region coupled to the semiconductor device layer and positioned to interact with electromagnetic radiation. The textured region can be a single textured region or multiple textured regions. Additionally, the pixel array can have a thickness less than 100 um and an external quantum efficiency of at least 75% for electromagnetic radiation having at least one wavelength greater than about 800 nm. The pixel array can have a pixel count, or also commonly known as the pixel resolution equal to or greater than about 320×240 (QVGA). In another embodiment the pixel resolution is greater than 640×480 (VGA), greater than 1 MP (megapixel), greater than 5 MP, greater than 15 MP and even greater than 25 MP.

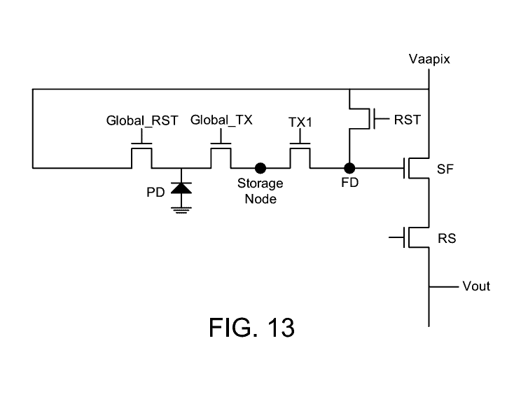

As is shown in FIG. 12, for example, a semiconductor device layer 1202 can include at least two pixels 1204 each having a first doped region 1206 and a second doped region 1208. A textured region 1210 can be positioned to interact with electromagnetic radiation. FIG. 13 shows a separate textured region for each pixel. In some aspects, however, a single textured region can be used to increase the absorption path lengths of multiple pixels in the array. Furthermore, an isolation structure 1212 can be positioned between the pixels to electrically and/or optically isolate the pixels from one another. In another aspect, the pixel array can be electronically coupled to electronic circuitry to process the signals generated by each pixel or pixel.

Various image sensor configurations and components are contemplated, and any such should be considered to be within the present scope. Non-limiting examples of such components can include a carrier wafer, transistors, electrical contacts, an antireflective layer, a dielectric layer, circuitry layer, a via(s), a transfer gate, an infrared filter, a color filter array (CFA), an infrared cut filter, an isolation feature, and the like. Various image sensor resolutions are also contemplated, and any such should be considered to be within the present scope. Non-limiting samples of such resolutions are so called QVGA, SVGA, VGA, HD 720, HD 1080, 4K, and the like. Additionally, such devices can have light absorbing properties and elements as has been disclosed in U.S. patent application Ser. No. 12/885,158, filed on Sep. 17, 2010 which is incorporated by reference in its entirety. It is further understood that the image sensor can be a CMOS (Complementary Metal Oxide Semiconductor) imaging sensor or a CCD (Charge Coupled Device).

Image sensor devices can include a number of transistors per pixel depending on the desired design of the device. In one aspect, for example, an image sensor device can include at least three transistors. In other aspects, an imaging device can have four, five, or six or more transistors. For example, FIG. 13 shows an exemplary schematic for a six-transistor (6-T) architecture that will allow global shutter operation according to one aspect of the present disclosure. The image sensor can include a pixel (PD), a global reset (Global_RST), a global transfer gate (Global_TX), a storage node, a transfer gate (TX1), reset (RST), source follower (SF), floating diffusion (FD), row select transistor (RS), power supply (Vaapix) and voltage out (Vout). Due to the use of extra transfer gate and storage node, correlated-double-sampling (CDS) is allowed. Therefore, the read noise should be able to match typical CMOS 4T pixels.

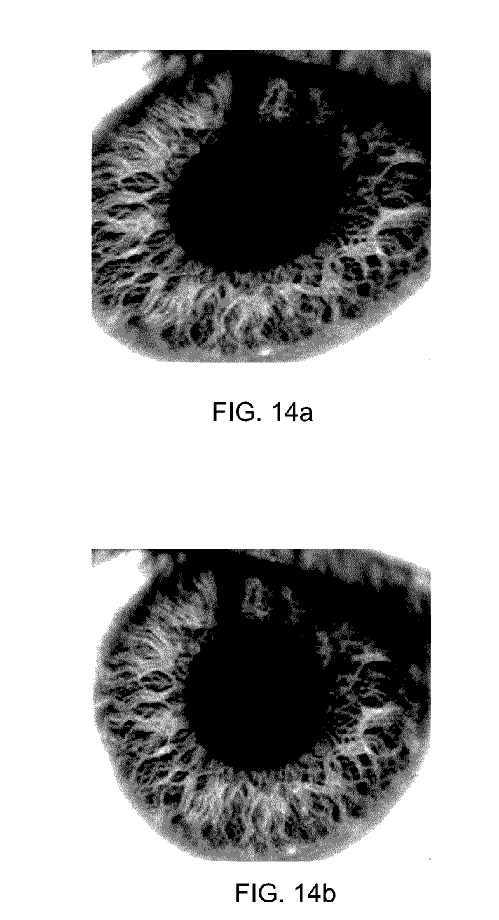

While a rolling shutter is considered to be within the present scope, the use of a global shutter can be beneficial for use in the present devices and systems. For example, FIGS. 14a-b show images of the iris of a subject captured by an IR sensitive image sensor device. As can be seen in FIG. 14a, an image of an iris captured using a rolling shutter is somewhat distorted due to movements during capture. These distortions may affect identification of the individual. FIG. 14b, on the other hand, shows an image of an iris captured using a global shutter that does not show such distortion. The global shutter operates by electronically activating all pixels at precisely the same time, allowing them to integrate the light from the scene at the same time and then stop the integration at the same time. This eliminates rolling shutter distortion.

In another aspect of the present disclosure, the biometric system can include a three dimensional (3D) photosensing image sensor. Such a 3D-type image sensor can be useful to image surface details of an individual for identification, such as facial features, body features, stride or body position features, ear features, and the like. Such 3D systems can include any applicable 3D technology, including, without limitation, Time-of-Flight (TOF), structured light, stereoscopic light, and the like. For example, TOF is one technique developed for use in radar and LIDAR (Light Detection and Ranging) systems to provide depth information that can be utilized for such 3D imaging. The basic principle of TOF involves sending a signal to an object and measuring a property of the returned signal from a target. The measured property is used to determine the time that has passed since the photon left the light source, i.e., TOF. Distance to the target is derived by multiplication of half the TOF and the velocity of the signal.

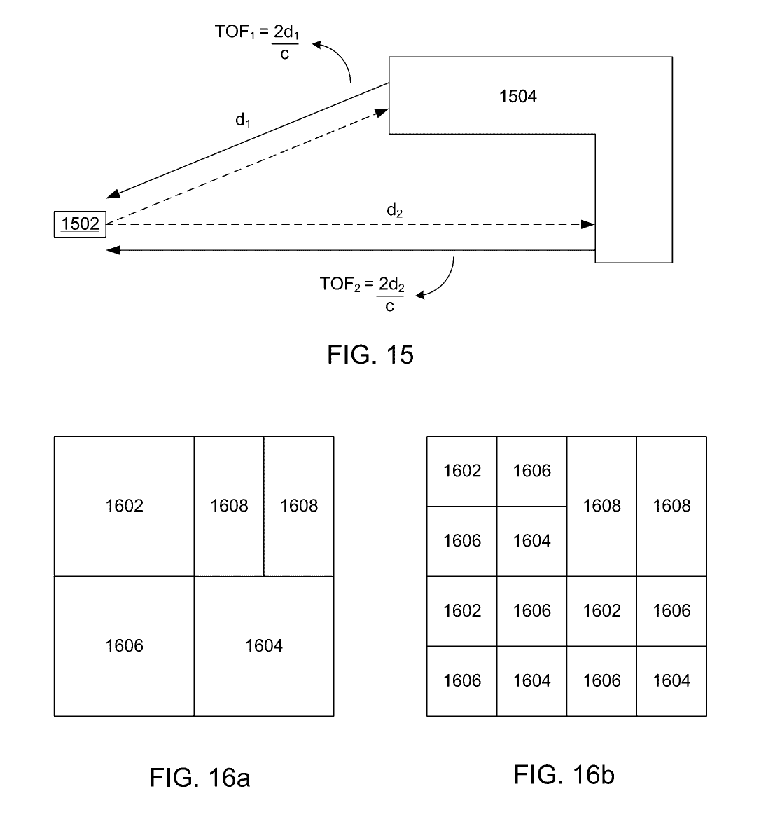

FIG. 15 illustrates a TOF measurement with a target having multiple surfaces that are separated spatially. Equation (III) can be used to measure the distance to a target where d is the distance to the target and c is the speed of light.

$$d = \frac{TOF * c}{2} \qquad ( III )$$

By measuring the time (e.g. TOF) it takes for light emitted from a light source 1502 to travel to and from a target 1504, the distance between the light source (e.g. a light emitting diode (LED)) and the surface of the target can be derived. For such an image sensor, if each pixel can perform the above TOF measurement, a 3D image of the target can be obtained. The distance measurements become difficult with TOF methods when the target is relatively near the source due to the high speed of light. In one aspect, therefore, a TOF measurement can utilize a modulated LED light pulse and measure the phase delay between emitted light and received light. Based on the phase delay and the LED pulse width, the TOF can be derived. As such, the TOF concept can be utilized in both CMOS and CCD sensors to obtain depth information from each pixel in order to capture an image used for identification of an individual.

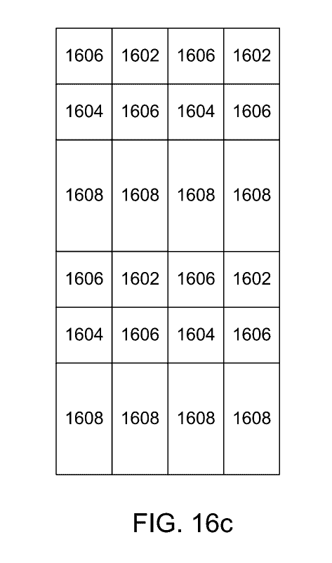

As one example, a 3D pixel, such as a TOF 3D pixel with enhanced infrared response can improve depth accuracy, which in turn can show facial features in a three dimensional scale. In one aspect, TOF image sensor has filters blocking visible light, and as such, may only detect IR light In another example, a 3D pixel, such as a TOF 3D pixel with enhanced infrared response can reduce the amount light needed to make an accurate distance calculation. In one aspect, an imaging array can include at least one 3D infrared detecting pixel and at least one visible light detecting pixel arranged monolithically in relation to each other. FIGS. 16a-c show non-limiting example configurations of pixel arrangements of such arrays. FIG. 16a shows one example of a pixel array arrangement having a red pixel 1602, a blue pixel 1604, and a green pixel 1606. Additionally, two 3D TOF pixels 1608 having enhanced responsivity or detectability in the IR regions of the light spectrum are included. The combination of two 3D pixels allows for better depth perception. In FIG. 16b, the pixel arrangement shown includes an image sensor as described in FIG. 16a and three arrays of a red pixel, a blue pixel, and two green pixels. Essentially, one TOF pixel replaces one quadrant of a RGGB pixel design. In this configuration, the addition of several green pixels allows for the capture of more green wavelengths that is needed for green color sensitivity need for the human eye, while at the same time capturing the infrared light for depth perception. It should be noted that the present scope should not be limited by the number or arrangements of pixel arrays, and that any number and/or arrangement is included in the present scope. FIG. 16c shows another arrangement of pixels according to yet another aspect.

In some aspects, the TOF pixel can have an on-pixel optical narrow band pass filter. The narrow band pass filter design can match the modulated light source (either LED or laser) emission spectrum and may significantly reduce unwanted ambient light that can further increase the signal to noise ratio of modulated IR light. Another benefit of increased infrared QE is the possibility of high frame rate operation for high speed 3D image capture. An integrated IR cut filter can allow a high quality visible image with high fidelity color rendering. Integrating an infrared cut filter onto the sensor chip can also reduce the total system cost of a camera module (due to the removal of typical IR filter glass) and reduce module profile (good for mobile applications). This can be utilized with TOF pixels and non-TOF pixels.

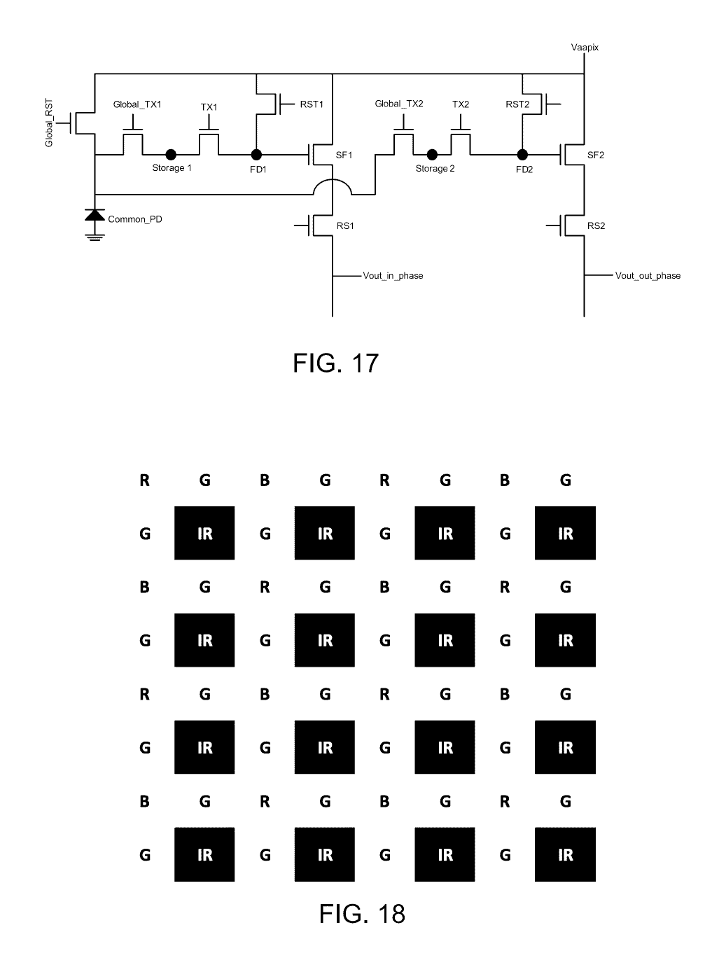

FIG. 17 shows an exemplary schematic of a 3D TOF pixel according to one aspect of the present disclosure. The 3D TOF pixel can have 11 transistors for accomplishing the depth measurement of the target. In this embodiment, the 3D pixel can include a pixel (PD), a global reset (Global_RST), a first global transfer gate (Global_TX1), a first storage node, a first transfer gate (TX1), a first reset (RST1), a first source follower (SF1), a first floating diffusion (FD1), a first row select transistor (RS1), a second global transfer gate (Global_TX2), a second storage node, a second transfer gate (TX2), a second reset (RST2), a second source follower (SF2), a second floating diffusion (FD2), a second row select transistor (RS2), power supply (Vaapix) and voltage out (Vout). Other transistors can be included in the 3D architecture and should be considered within the scope of the present invention. The specific embodiment with 11 transistors can reduce motion artifacts due to the global shutter operation, thereby giving more accurate measurements.

As another example of a pixel array structure that can be beneficial, particularly where both IR and visible light are being detected, IR filtering can be integrated with visible light filtering to generate unique pixel arrays. For example, a traditional Bayer array includes two green, one red, and one blue selective pixel(s). Larger array patterns can be utilized that maintain an approximate ratio of selectively while at the same time allowing for interspersed IR selective pixel filtering to achieve enhanced image sensor functionality. This is particularly useful for image sensors according to aspects of the present disclosure that contain pixels that can detect light from the visible range and up into the IR range. For example, in one aspect an image sensor according to aspects of the present disclosure can detect light having wavelengths of from about 400 nm to about 1200 nm. Thus, in addition to detectability in the IR range, such a silicon image sensor is also selective to light in the visible range, from about 400 nm to about 700 nm. Thus by functionally coupling various filtering devices to an array of such pixels, selective detection can be achieved in the green range, the blue range, the red range, and the IR range. It is noted that filters can be also be configured to be movable into and out of the path of incoming electromagnetic radiation.

In one aspect, for example, a plurality of filters can be arranged in a Bayer pattern and configured to pass predetermined electromagnetic radiation having wavelengths ranging from about 400 nm to about 700 nm, as well as wavelengths greater than 850 nm. In another aspect, the visible electromagnetic radiation can include wavelengths from about 400 nm to about 700 nm and the infrared electromagnetic radiation can include at least one wavelength greater than about 900 nm, and in some cases at about 940 nm.

Specific patterns of pixel arrays can vary depending on the desired characteristics of the device. In one aspect, for example, the Bayer pattern can be modified using filters to replace one or more visible light selective pixels with an IR selective pixel. Any of the green, red, or blue pixels can be modified to detect IR light over the pixel array. As one example, maintaining the green selectivity of the array can be achieved by using a plurality of first 2×2 filters including two green-pass pixel filters, one infrared-pass pixel filter, and one blue-pass pixel filter, and a plurality of first 2×2 filters including two green-pass pixel filters, one infrared-pass pixel filter, and one red-pass pixel filter. These 2×2 filters can then be alternated to provide a uniform red/blue selective pattern across the array. One exemplary implementation is shown in FIG. 18. Additionally, it is noted that either of the green pixels can be replaced with IR selective pixel functionality as well.

Additionally, it is also contemplated that electromagnetic radiation can be filtered to allow passage of a visible range and an IR range using either multiple or single filters. For example, light can be filtered to allow passage of visible light and IR light having at least one wavelength above 900 nm. By providing a notch filter in between these ranges, signal-to-noise ratio can be increased. Furthermore, a narrow pass filter centered around the emission wavelength of the active light source can further improve the efficiency of the image sensor. One example of such a filter is a dichroic cut filter, allowing visible light to pass along with IR light above 930 nm, but filtering out light having a wavelength of between about 700 nm and about 930 nm.

Furthermore, narrow IR filtering can facilitate further processing of the resulting image. For example, by using a narrow IR filtering, combined with a short integration time, the visible image can be subtracted from the IR filtered image to generate an improved IR image. The resulting image can also be processed using correlated double sampling with a visible frame followed by an IR frame and again by a visible frame followed by averaging of the visible frames for use in offset subtraction.

As has been described, the system for identifying an individual can include a light source that is either a passive light source (e.g. sunlight, ambient room lighting) or an active light source (e.g. an LED or lightbulb) that is capable of emitting IR light. The system can utilize any source of light that can be beneficially used to identify an individual. As such, in one aspect the light source is an active light source. Active light sources are well known in the art that are capable of emitting light, particularly in the IR spectrum. Such active light sources can be continuous or pulsed, where the pulses can be synchronized with light capture at the imaging device. While various light wavelengths can be emitted and utilized to identify an individual, IR light in the range of from about 700 nm to about 1200 nm can be particularly useful. Additionally, in some aspects the active light source can be two or more active light sources each emitting infrared electromagnetic radiation at distinct peak emission wavelengths. While any distinct wavelength emissions within the IR range can be utilized, non-limiting examples include 850 nm, 940 nm, 1064 nm, and the like. In some aspects, the two or more active light sources can interact with the same image sensor device, either simultaneously or with an offset duty cycle. Such configurations can be useful for independent capture of one or more unique features of the individual for redundant identification. This redundant identification can help insure accurate authorization or identification of the individual. In other aspects, the two or more active light sources can each interact with a different image sensor device. In another aspect, the device can determine if the ambient light is sufficient to make an identification and thereby conserve battery life by not using an active light source. An image sensor with enhanced infrared quantum efficiency increases the likelihood of the ambient light being sufficient for passive measurement.

As has been described, the system can include an analysis module functionally coupled to the image sensor device to compare the at least one biometric feature with a known and authenticated biometric feature to facilitate identification of the individual. For example, the analysis module can obtain known data regarding the identity of an individual from a source such as a database and compare this known data to the electronic representation being captured by the image sensor device. Various algorithms are known that can analyze the image to define the biometric boundaries/measurements and convert the biometric measurements to a unique code. The unique code can then be stored in the database to be used for comparison to make positive identification of the individual. Such an algorithm has been described for iris detection in U.S. Pat. Nos. 4,641,349 and 5,291,560, which are incorporated by reference in their entirety. It should be noted that the image processing module and the analysis module can be the same or different modules. It is understood that the system described herein can be utilized with any of the identification algorithm.

Furthermore, it is noted that in various aspects the present systems can be sized to suit a variety of applications. This is further facilitated by the increased sensitivity of the image sensor devices to IR light and the corresponding decrease in the intensity of IR emission, thus allowing reduction in the size of the light source or number of light sources. In one aspect, for example, the light source, the image sensor device, and the image processing module collectively have a size of less than about 250 cubic millimeters. In one aspect, for example, the light source, the image sensor device, and the image processing module collectively have a size of less than about 160 cubic millimeters. In one aspect, for example the image sensor device, lens system, and the image processing module collectively have a size of less than about 130 cubic millimeters. In one aspect, for example, the image sensor is incorporated into a camera module that includes but is not limited to a lens and focusing elements and said module is less than 6 mm thick in the direction of incoming electromagnetic radiation. In yet another aspect, the light source, the image sensor device, and the image processing module collectively have a size of less than about 16 cubic centimeters. In one aspect, the image sensor device can have an optical format of about 1 inch. In one aspect, the image sensor device can have an optical format of about ½ inch. In one aspect, the image sensor device can have an optical format of about ⅓ inch. In one aspect, the image sensor device can have an optical format of about ¼ inch. In one aspect, the image sensor device can have an optical format of about 1/7 inch. In yet another aspect, the image sensor device can have an optical format of about 1/10 inches.

In other aspects, the identification system can be integrated into an electronic device. Non-limiting examples of such devices can include mobile smart phones, cellular phones, laptop computers, desktop computers, tablet computers, ATMs, televisions, video game consoles and the like. In one specific aspect, positive identification of the individual is operable to unlock the electronic device. In this example, the electronic device stores an encrypted authorized user's facial and iris identification trait in a storage registry and an individual's identification traits are captured by an authorization system incorporated into the electronic device. The authorization system can compare the individual's identification trait with the stored authorized user's identification trait for positive identification. This aspect is beneficial for verifying an individual in a financial or legal transaction or any other transaction that requires identification and/or signature. It is contemplated herein, that ATM financial transactions may include a user authorization system where the encrypted authorized user's identification trait is stored on an ATM debit card, such that the ATM device can compare the individual's identification trait with the authorized user trait stored on the card for a positive identification. A similar system can be utilized for credit cards or any other item of commerce.

In another example, a financial transaction may be accomplished via a cell phone device where the authorization system is continuously verifying the authorized user during the duration of the financial transaction via a front side or cameo imaging devices incorporated into the cell phone. Furthermore, in a cell phone embodiment, the image sensor device can include a switch such that the user can toggle between infrared light capture and visible light capture modes.

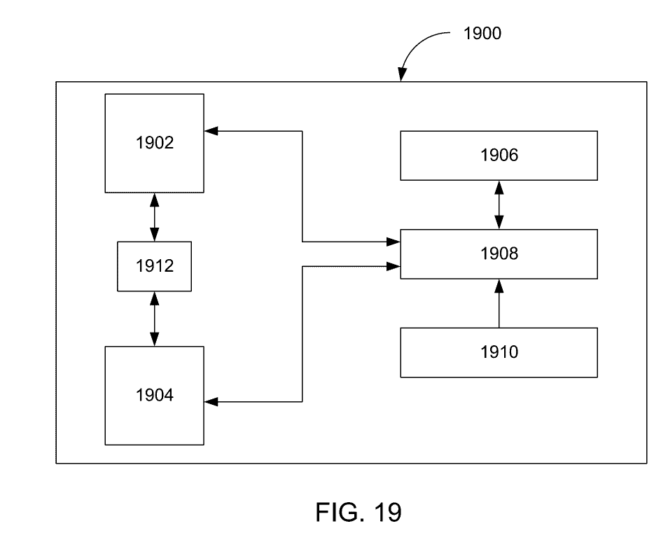

In FIG. 19, an electronic device can include an integrated user authorization system 1900 that can be configured to continuously verify and authorize a user. Such a system can include an image sensor device 1902 including a semiconductor device layer having a thickness of less than about 10 microns, at least two doped regions forming a junction, and a textured region positioned to interact with the electromagnetic radiation as has been described, where the image sensor device is positioned to capture an electronic representation of an identification trait of a user of the device. It is noted that the thickness of the semiconductor device layer can vary depending on the design of the device. As such, the thickness of the semiconductor device layer should not be seen as limiting, and additionally includes other thicknesses. Non-limiting examples include less than about 20 microns, less than about 30 microns, less than about 40 microns, less than about 50 microns, etc. The image sensor device at least periodically captures an electronic representation of the user. The system can also include a storage register 1906 operable to store a known identification trait of an authorized user and an analysis module 1908 electrically coupled to the image sensor device and the storage register, where the analysis module is operable to use algorithms to generated an electronic representation and compare the electronic representation of the identification trait to the known identification trait to verify that the user is the authorized user. Thus an authorized user can continuously use the device while an unauthorized user will be precluded from doing so. In one aspect, the system can include a light source operable to emit electromagnetic radiation having at least one wavelength of from about 700 nm to about 1200 nm toward the user.

In another aspect, a second image sensor device 1904 can be incorporated into the system. The second image sensor device can be an IR enhanced imaging device configured to detect electromagnetic radiation having a wavelength in the range of about 800 nm to about 1200 nm. The second image sensor device can be configured to exclusively track an individual iris, face or both. In another aspect the second image sensor device can be configured to detect visible light and can be cameo type image sensor. In another embodiment, a trigger 1910 (e.g. motion sensor) and a switch 1912 can optionally be incorporated in the user authorization system allowing the system to be activated and toggled between a first image sensor device and a second image sensor device. Furthermore, a first or second image sensor device can include a lens or optic element for assisting in the capturing the electronic representation of an individual.

Given the continuous nature of the user authorization system, it can be beneficial to separate the authorization system from the primary processing system of the electronic device in order to decrease central processing unit (CPU) load. One technique for doing so includes monolithically integrating an analysis module and the image sensor device together on the same semiconductor device and separate from the CPU of the electronic device. In this way the authorization system functions independently from the CPU of the electronic device.

Furthermore, in some aspects the authorization system can include a toggle to switch the image sensor device between IR light capture and visible light capture. As such, the image sensor can switch between authorizing the user and capturing visible light images. In some aspects the authorization system can capture both IR and visible light simultaneously and use image processing to authorize the user.

Furthermore, it can be beneficial to encrypt the known identification trait for security reasons. Such encryption can protect an authorized user from identity theft or unauthorized use of an electronic device.

A variety of biometric features can be utilized to identify an individual, and any feature capable of being utilized for such identification is considered to be within the present scope. Non-limiting examples of such identification traits include iris structure and patterns, external facial patterns, intrafacial distances, ocular patterns, earlobe shapes, and the like. External facial patterns can include inter-pupilary distance, two dimensional facial patterns, three dimensional facial patterns, and the like. In one specific aspect, the substantially unique identification trait can include an electronic representation of an iris sufficient to identify the individual. As has been described, the enhanced sensitivity of the present system can facilitate the capture of an electronic representation of the iris using a minimum amount of near infrared light.

In one aspect the image sensor can be a front side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 30% for electromagnetic radiation having at least one wavelength of greater than 900 nm and a modulation transfer function (MTF) of over 0.3 (as measured by the slant edge technique at half Nyquist) at one wavelength greater than 900 nm.

In one aspect the image sensor can be a front side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 30% for electromagnetic radiation having at least one wavelength of greater than 900 nm and a modulation transfer function (MTF) of over 0.4 (as measured by the slant edge technique at half Nyquist) at one wavelength greater than 900 nm.

In another aspect the image sensor can be a front side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 30% for electromagnetic radiation having at least one wavelength of greater than 900 nm and a modulation transfer function (MTF) of over 0.5 (as measured by the slant edge technique at half Nyquist) at one wavelength greater than 900 nm.

In a further aspect, the image sensor can be a back side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 40% for electromagnetic radiation having at least one wavelength of greater than 900 nm and a modulation transfer function (MTF) of over 0.4 (as measured by the slant edge technique at half Nyquist) at one wavelength greater than 900 nm.

In one specific embodiment the system includes a silicon image sensor with a device layer having a thickness of less than about 10 microns, at least two doped regions forming a junction, and a textured region positioned to interact with the reflected electromagnetic radiation, wherein the image sensor has an external quantum efficiency of at least about 30% for electromagnetic radiation having at least one wavelength of greater than 900 nm and a modulation transfer function (MTF) of over 0.4 (as measured by the slant edge technique at half Nyquist) at one wavelength greater than 900 nm. In one aspect, the silicon image sensor in the system is ¼ inch optical format with a resolution of 1 MP or higher. In another aspect, the silicon image sensor in the system is ⅓ inch optical format with a resoluation of 3 MP or higher. In one aspect, the image sensor is incorporated into a camera module that is less than 150 cubic millimeters in volume. In another aspect the system is incorporated into a mobile phone. In one aspect, the biometric signature that is measured is iris structure. In yet another aspect, the active illumination source is one or many 940 nm light emitting diodes. In another aspect the image sensor is incorporated into a camera module with a field of view less than 40 degrees. In yet another aspect, the image sensor module includes a built in filter that only allows transmission on near infrared light.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A system for authenticating a user through identification of at least one biometric feature, comprising:
an active light source capable of emitting electromagnetic radiation having a peak emission wavelength at from about 700 nm to about 1200 nm, the active light source being positioned to emit the electromagnetic radiation to impinge on at least one biometric feature of the user;
an image sensor having infrared light-trapping pixels positioned relative to the active light source to receive and detect the electromagnetic radiation upon reflection from the at least one biometric feature of the user, the light trapping pixels having a structural configuration to facilitate multiple passes of infrared electromagnetic radiation therethrough;
a processing module functionally coupled to the image sensor and operable to generate an electronic representation of the at least one biometric feature of the user from detected electromagnetic radiation;
an authentication module functionally coupled to the processing module operable to receive and compare the electronic representation to an authenticated standard of the at least one biometric feature of the user to provide authentication of the user; and
an authentication indicator functionally coupled to the authentication module operable to provide notification that the user is authenticated.

2. The system of claim 1, wherein the image sensor is capable of detecting electromagnetic radiation having wavelengths of from about 400 nm to about 1200 nm.

3. The system of claim 1, wherein the active light source generates electromagnetic radiation having an intensity of less than about 5 uW/cm² at 940 nm.

4. The system of claim 1, wherein at least the active light source, the image sensor, the processing module, and the authentication indicator are integrated into an electronic device.

5. The system of claim 4, wherein the electronic device is a hand held electronic device, a cellular phone, a smart phone, a tablet computer, a personal computer, an automated teller machine, a kiosk, a credit card terminal, a television, a video game console, or a combination thereof.

6. The system of claim 4, wherein the image sensor is incorporated into a cameo camera of the electronic device.

7. The system of claim 1, wherein the active light source has a peak emission wavelength at from about 850 nm to about 1100 nm.

8. The system of claim 1, wherein the active light source has a peak emission wavelength at about 940 nm.

9. The system of claim 1, wherein the active light source is operated in a continuous manner, a strobed manner, a user activated manner, a structured light manner, an authentication activated manner, or a combination thereof.

10. The system of claim 1, wherein the image sensor is a front side illuminated image sensor including a semiconductor device layer having a thickness of less than about 10 microns, at least two doped regions forming a junction, and a textured region positioned to interact with the reflected electromagnetic radiation, wherein the image sensor has a an external quantum efficiency of at least about 20% for electromagnetic radiation having at least one wavelength of greater than 900 nm.

11. The system of claim 1, wherein the image sensor is a front side illuminated image sensor including a semiconductor device layer having a thickness of less than about 10 microns, at least two doped regions forming a junction, and a textured region positioned to interact with the reflected electromagnetic radiation, wherein the image sensor has an external quantum efficiency of at least about 30% for electromagnetic radiation having at least one wavelength of greater than 900 nm.

12. The system of claim 1, wherein the image sensor is a back side illuminated image sensor including a semiconductor device layer having a thickness of less than about 10 microns, at least two doped regions forming a junction, and a textured region positioned to interact with the reflected electromagnetic radiation, wherein the image sensor an external quantum efficiency of at least about 40% for electromagnetic radiation having at least one wavelength of greater than 900 nm.

13. The system of claim 1, wherein the image sensor is a CMOS image sensor.

14. The system of claim 1, further comprising a synchronization component functionally coupled between the image sensor and the active light source, the synchronization component being capable of synchronizing the capture of reflected electromagnetic radiation by the image sensor with emission of electromagnetic radiation by the active light source.

15. The system of claim 14, wherein the synchronization component includes circuitry, software, or combinations thereof, configured to synchronize the image sensor and the active light source.

16. The system of claim 1, wherein the active light source is two or more active light sources each emitting electromagnetic radiation at distinct peak emission wavelengths.

17. The system of claim 16, wherein the two or more active light sources emit electromagnetic radiation at about 850 nm and about 940 nm.

18. The system of claim 1, wherein the image sensor is capable of capturing the reflected electromagnetic radiation with sufficient detail to facilitate the authentication of the user using electromagnetic radiation emitted from the active light source having at least one wavelength of from about 700 nm to about 1200 nm and having a scene radiance impinging on the user at 18 inches that is less than about 5 uW/cm².

19. The system of claim 1, wherein the image sensor is capable of capturing the reflected electromagnetic radiation with sufficient detail to facilitate the authentication of the user using the electromagnetic radiation emitted from the active light source having a peak emission wavelength of about 940 nm and having a scene radiance impinging on the user at 18 inches that is less than about 5 uW/cm².

20. The system of claim 1, wherein the biometric feature is an external facial pattern, an ocular pattern, an iris pattern, an earlobe pattern, or a combination thereof.

21. The system of claim 1, wherein at least one of the authentication module or the processing module is integrated monolithically together with the image sensor but separate from a main CPU of the electronic device.

22. The system of claim 1, further comprising a plurality of filters functionally coupled to the image sensor.

23. The system of claim 22, wherein the plurality of filters are arranged in a Bayer pattern and configured to filter predetermined electromagnetic radiation having wavelengths ranging from about 400 nm to about 700 nm.

24. The system of claim 1, further comprising a filter configured to allow predetermined visible and infrared electromagnetic radiation to pass through the filter.

25. The system of claim 24, wherein the visible electromagnetic radiation includes wavelengths from about 400 nm to about 700 nm and the infrared electromagnetic radiation includes at least one wavelength greater than about 900 nm.

26. A system for authorizing a user on a secure resource, comprising:
the system for authenticating the user of claim 4;
an authorization module functionally coupled to the authentication module, the authorization module operable to verify the authentication of the user and to allow access to at least a portion of the secure resource.

27. The system of claim 26, wherein the secure resource is physically separate and distinct from the electronic device.

28. The system of claim 27, wherein at least one of the authentication module or the authorization module is located within the electronic device.

29. The system of claim 27, wherein at least one of the authentication module or the authorization module is located with the secure resource.

30. The system of claim 26, wherein the secure resource is located within the electronic device.

31. The system of claim 30, wherein the secure resource is a gateway to a remote secure resource.

32. The system of claim 26, wherein authorization of the user is operable to verify the user in a financial transaction with the secure resource.

33. The system of claim 26, wherein at least one of the authentication module or the authorization module is integrated monolithically together with the image sensor but separate from a CPU of the electronic device.

34. A method of authorizing a user with an electronic device for using a secure resource, comprising:
delivering electromagnetic radiation from an active light source in the electronic device to impinge on the user such that the electromagnetic radiation reflects off of at least one biometric feature of the user, the electromagnetic radiation having a peak emission wavelength of from about 700 nm to about 1200 nm;
detecting the reflected electromagnetic radiation at an image sensor positioned in the electronic device, wherein the image sensor includes infrared light-trapping pixels positioned relative to the active light source to receive and detect the electromagnetic radiation upon reflection from the at least one biometric feature of the user, the light trapping pixels having a structural configuration to facilitate multiple passes of infrared electromagnetic radiation therethrough;
generating an electronic representation of the at least one biometric feature of the user from the reflected electromagnetic radiation;
comparing the electronic representation to an authenticated standard of the at least one biometric feature of the user to authenticate the user as an authenticated user; and
authorizing the authenticated user to use at least a portion of the secure resource.

35. The method of claim 34, further comprising providing notification to the user that authorization was successful and that an authorization state is active.

36. The method of claim 34, wherein the biometric feature is an external biometric pattern, an ocular pattern, an iris pattern, an earlobe pattern, or a combination thereof.

37. The method of claim 34, further comprising periodically authenticating the user while the secure resource is in use.

38. The method of claim 34, wherein the user authorization system is operable to continuously verify the user as the authorized user.

39. The method of claim 34, wherein delivering electromagnetic radiation and detecting the reflected electromagnetic radiation further includes:
delivering electromagnetic radiation having a peak emission wavelength of about 940 nm in a pulsatile manner;
detecting the reflected electromagnetic radiation coinciding with the pulsatile 940 nm electromagnetic radiation;
detecting visible electromagnetic radiation with the image sensor;
subtracting the detected visible electromagnetic radiation from the reflected electromagnetic radiation to generate the electronic representation.
